(19) United States
(12) Patent Application Publication
(10) Pub. No.: US 2026/0333927 A1
(43) Pub. Date: Oct. 22, 2026

(54) PHOTOELECTRIC CONVERSION DEVICE

(71) Applicant: CANON KABUSHIKI KAISHA, Tokyo (JP)

(72) Inventors: KAZUKI NISHIMURA, Tokyo (JP); YUSUKE ONUKI, Kanagawa (JP); HIROMASA TSUBOI, Tokyo (JP)

(21) Appl. No.: 19/636,180

(22) Filed: Apr. 1, 2026

(30) Foreign Application Priority Data
Apr. 17, 2025 (JP) 2025-068401
Jan. 21, 2026 (JP) 2026-008099

(51) Int. Cl. H10F 39/00; H04N 25/778; H04N 25/78

(52) U.S. Cl. CPC H10F 39/811; H04N 25/778; H04N 25/78

(57) ABSTRACT

A photoelectric conversion device includes a first photoelectric conversion unit, a floating diffusion, a first transfer transistor configured to transfer charges from the first photoelectric conversion unit to the floating diffusion, a first wiring connected to a gate electrode of the first transfer transistor, a second wiring connected to the floating diffusion, a third wiring to which a predetermined potential is applied, a fourth wiring arranged at least partially side by side with the third wiring and generating a capacitance with the third wiring, and a capacitance addition transistor having a first main electrode connected to the floating diffusion and a second main electrode connected to the fourth wiring. In a plan view with respect to the semiconductor substrate, the fourth wiring is arranged between the first wiring and the second wiring.

### BACKGROUND

### Field of the Technology

The present disclosure relates to a photoelectric conversion device.

### Description of the Related Art

International Publication No. WO2016/098624 discloses a photoelectric conversion device including a photodiode and a transfer gate that transfers charges from the photodiode to a floating diffusion.

### SUMMARY

According to one aspect of the present disclosure, there is provided a photoelectric conversion device including a semiconductor substrate, a first photoelectric conversion unit formed in the semiconductor substrate, a floating diffusion formed in the semiconductor substrate, a first transfer transistor formed in the semiconductor substrate and configured to transfer charges from the first photoelectric conversion unit to the floating diffusion, a first wiring connected to a gate electrode of the first transfer transistor, a second wiring connected to the floating diffusion, a third wiring to which a predetermined potential is applied, a fourth wiring arranged at least partially side by side with the third wiring and generating a capacitance with the third wiring, and a capacitance addition transistor formed in the semiconductor substrate and having a first main electrode connected to the floating diffusion and a second main electrode connected to the fourth wiring. In a plan view with respect to the semiconductor substrate, the fourth wiring is arranged between the first wiring and the second wiring.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram illustrating an overall configuration example of a photoelectric conversion device according to a first embodiment.

FIG. 2 is a circuit diagram illustrating a configuration example of a pixel according to the first embodiment.

FIG. 3 is a plan view illustrating a configuration example of the pixel according to the first embodiment.

FIG. 4 is a cross-sectional view illustrating a configuration example of the pixel according to the first embodiment.

FIG. 5 is a cross-sectional view illustrating a configuration example of the pixel according to the first embodiment.

FIG. 6 is a circuit diagram illustrating a configuration example of a pixel according to a second embodiment.

FIG. 7 is a plan view illustrating a configuration example of the pixel according to the second embodiment.

FIG. 8 is a plan view illustrating a configuration example of a pixel according to a third embodiment.

FIG. 9 is a circuit diagram illustrating a configuration example of a pixel according to a fourth embodiment.

FIG. 10 is a plan view illustrating a configuration example of the pixel according to the fourth embodiment.

FIG. 11 is a plan view illustrating a configuration example of a pixel according to a fifth embodiment.

FIG. 12 is a plan view illustrating a configuration example of a pixel according to a sixth embodiment.

FIG. 13 is a circuit diagram illustrating a configuration example of a pixel according to a seventh embodiment.

FIG. 14 is a plan view illustrating a configuration example of the pixel according to the seventh embodiment.

FIG. 15 is a circuit diagram illustrating a configuration example of a pixel according to an eighth embodiment.

FIG. 16 is a plan view illustrating a configuration example of the pixel according to the eighth embodiment.

FIG. 17 is a plan view illustrating a configuration example of the pixel according to the eighth embodiment.

FIG. 18 is a plan view illustrating an arrangement example of color filters according to the eighth embodiment.

FIG. 19 is a cross-sectional view illustrating a configuration example of the pixel according to the eighth embodiment.

FIG. 20 is a circuit diagram illustrating a configuration example of a pixel according to a ninth embodiment.

FIG. 21 is a plan view illustrating a configuration example of the pixel according to the ninth embodiment.

FIG. 22 is a plan view illustrating an arrangement example of color filters according to the ninth embodiment.

FIG. 23 is a plan view illustrating a configuration example of a pixel according to a tenth embodiment.

FIG. 24 is a block diagram illustrating a schematic configuration of equipment according to an eleventh embodiment.

FIGS. 25A and 25B are block diagrams illustrating a schematic configuration of equipment according to a twelfth embodiment.

### DESCRIPTION OF THE EMBODIMENTS

In a photoelectric conversion device as disclosed in International Publication No. WO2016/098624, a settling time of a potential of a floating diffusion may affect an operation speed. The following disclosure relates to a photoelectric conversion device with improved operation speed.

Hereinafter, embodiments will be described in detail with reference to the accompanying drawings. Note that the following embodiments do not limit the technology according to the claims. Although a plurality of features are described in the embodiments, not all of the plurality of features are essential to the claimed technology. Further, the plurality of features may be combined as appropriate. Throughout the drawings, the same or corresponding elements are denoted by the same reference numerals, and redundant description thereof may be omitted or simplified.

In the embodiments described below, an imaging device will be mainly described as an example of a photoelectric conversion device. However, the photoelectric conversion device in each embodiment is not limited to the imaging device, and can be applied to other photodetection devices based on photoelectric conversion. Examples of other photodetection devices include a ranging device and a photometric device. The ranging device may be, for example, a focus detection device, a distance measuring device using time-of-flight (TOF), or the like. The photometric device may be a device that measures the amount of light incident on the device.

Hereinafter, a semiconductor region of a first conductivity type having the same carriers as the signal carriers as the majority carriers is an N-type semiconductor region, and a semiconductor region of a second conductivity type is a P-type semiconductor region. That is, the signal carriers are electrons. In addition, an anode of a photodiode constituting a photoelectric conversion unit is of an N-type, and a cathode of the photodiode is of a P-type. The polarity and the conductivity type may be opposite to those described above. That is, the signal carriers may be holes, the semiconductor region of the first conductivity type may be the P-type semiconductor region, and the semiconductor region of the second conductivity type may be the N-type semiconductor region. The anode of the photodiode constituting the photoelectric conversion unit may be the P-type, and the cathode of the photodiode may be the N-type. In this case, the voltage relationship is also reversed.

### First Embodiment

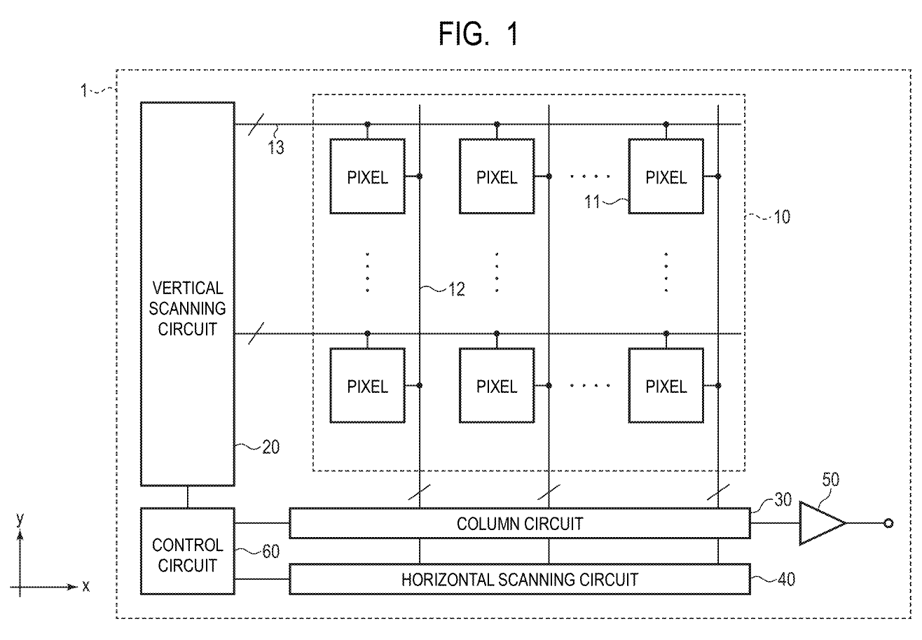

FIG. 1 is a block diagram illustrating an overall configuration example of a photoelectric conversion device 1 according to the present embodiment. The photoelectric conversion device 1 includes a pixel array 10, a vertical scanning circuit 20, a column circuit 30, a horizontal scanning circuit 40, an output circuit 50, and a control circuit 60. The pixel array 10 includes a plurality of pixels 11 arranged in an x direction and a y direction and forming a plurality of rows and a plurality of columns. The vertical scanning circuit 20, the column circuit 30, the horizontal scanning circuit 40, the output circuit 50, and the control circuit 60 are driving circuits of the photoelectric conversion device 1.

In the pixel array 10, a scanning line 13 is arranged for each row, and an output signal line 12 is arranged for each column. The scanning line 13 is connected to the vertical scanning circuit 20, and the output signal line 12 is connected to the column circuit 30. Although one signal line is illustrated in one row as the scanning line 13 in FIG. 1, the scanning line 13 in one row may include a plurality of signal lines. The plurality of signal lines supply different control signals to the pixels 11. Although one output signal line 12 is illustrated in one column in FIG. 1, a plurality of output signal lines 12 may be arranged in one column.

In FIG. 1, the drive circuit is arranged around the pixel array 10. However, the position where the driving circuit is arranged is not limited thereto. For example, in a case where the photoelectric conversion device 1 is a stacked type in which a plurality of semiconductor substrates are stacked, the drive circuit unit may be arranged in a region overlapping the pixel array 10 in a plan view. Note that, in this specification, the plan view refers to viewing a surface parallel to a light incident surface of a substrate including the photoelectric conversion unit from a normal direction of the surface parallel to the light incident surface.

Each of the plurality of pixels 11 converts light into an electrical signal. Each of the plurality of pixels 11 outputs the generated electrical signal to the column circuit 30 via the output signal line 12 of the corresponding column.

The control circuit 60 supplies, to the vertical scanning circuit 20, the column circuit 30, and the horizontal scanning circuit 40, control signals for controlling operation timings and the like of the respective units. The vertical scanning circuit 20 outputs control signals for controlling the pixels 11 for each row via the scanning line 13. The vertical scanning circuit 20 performs scanning for sequentially selecting the pixels 11 in each row, and outputting signals from the selected pixels 11 to the output signal lines 12.

The column circuit 30 performs signal processing on the electrical signal input from the pixel 11 for each column. This signal processing may include, for example, noise removal, signal amplification, and the like.

The horizontal scanning circuit 40 supplies control signals to the column circuit 30 for sequentially outputting the signal processed in the column circuit 30 to the output circuit 50 for each column. The output circuit 50 outputs the signal output from the column circuit 30 to the outside of the photoelectric conversion device 1. A device to which the signal output from the photoelectric conversion device 1 is input may be, for example, a storage device or a signal processing device.

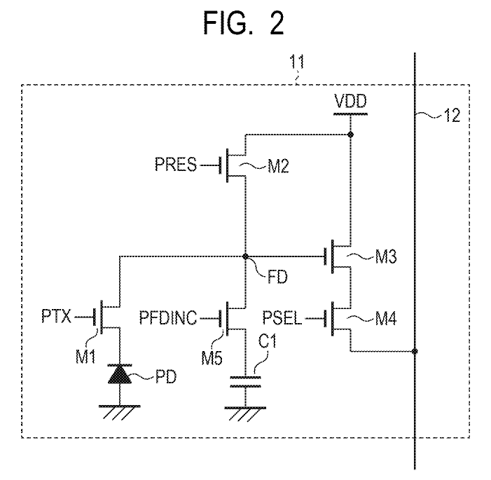

FIG. 2 is a circuit diagram illustrating a configuration example of the pixel 11 according to the present embodiment. The pixel 11 includes a photoelectric conversion unit PD, a capacitive element C1, a transfer transistor M1, a reset transistor M2, an amplification transistor M3, a selection transistor M4, and a capacitance addition transistor M5. The transfer transistor M1, the reset transistor M2, the amplification transistor M3, the selection transistor M4, and the capacitance addition transistor M5 are N-type metal-oxide-semiconductor (MOS) transistors. A drain and a source of each transistor may be collectively referred to as main electrodes.

The photoelectric conversion unit PD (first photoelectric conversion unit) is a photoelectric conversion element that generates and accumulates charges according to incident light by photoelectric conversion. The photoelectric conversion unit PD is typically a photodiode.

An anode of the photoelectric conversion unit PD is connected to a ground line having a ground potential. A cathode of the photoelectric conversion unit PD is connected to a source of the transfer transistor M1 (first transfer transistor). A drain of the transfer transistor M1 is connected to a source of the reset transistor M2, a drain of the capacitance addition transistor M5, and a gate of the amplification transistor M3. A connection node between the drain of the transfer transistor M1, the source of the reset transistor M2, the drain of the capacitance addition transistor M5, and the gate of the amplification transistor M3 is a floating diffusion FD. The floating diffusion FD has a parasitic capacitance parasitic to a semiconductor region or the like constituting these transistors, and holds charges transferred from the photoelectric conversion unit PD.

The capacitive element C1 is an interwire capacitance formed in a wiring layer and has a first terminal and a second terminal. A source of the capacitance addition transistor M5 is connected to the first terminal of the capacitive element C1. The second terminal of the capacitive element C1 is connected to a ground line having the ground potential.

A drain of the reset transistor M2 and a drain of the amplification transistor M3 are connected to a power supply line having a power supply potential VDD. A source of the amplification transistor M3 is connected to a drain of the selection transistor M4. A source of the selection transistor M4 is connected to the output signal line 12.

The vertical scanning circuit 20 supplies a control signal PTX to a gate of the transfer transistor M1 via one signal line constituting the scanning line 13. When the transfer transistor M1 is turned on according to the control signal PTX, the charges accumulated in the photoelectric conversion unit PD is transferred to the floating diffusion FD.

The vertical scanning circuit 20 supplies a control signal PRES to a gate of the reset transistor M2 via one signal line constituting the scanning line 13. When the reset transistor M2 is turned on according to the control signal PRES, the charges transferred to the floating diffusion FD is discharged, and the potential of the floating diffusion FD is reset.

The vertical scanning circuit 20 supplies a control signal PSEL to a gate of the selection transistor M4 via one signal line constituting the scanning line 13. When the selection transistor M4 is turned on according to the control signal PSEL, a signal is output from the amplification transistor M3 in the corresponding row to the output signal line 12. At this time, the amplification transistor M3 and a current source (not illustrated) connected to the output signal line 12 constitute a source follower circuit that outputs a signal corresponding to the charges transferred to the floating diffusion FD, thereby functioning as an amplification unit.

The vertical scanning circuit 20 supplies a control signal PFDINC to a gate of the capacitance addition transistor M5 via one signal line constituting the scanning line 13. When the capacitance addition transistor M5 is turned on according to the control signal PFDINC, the capacitance of the capacitive element C1 is connected in parallel to the capacitance of the floating diffusion FD, and the substantial capacitance of the floating diffusion FD increases. At this time, as compared with a case where the capacitance addition transistor M5 is in the off state, the conversion efficiency from the charge to the voltage in the floating diffusion FD decreases. Accordingly, for example, it is possible to suppress whiteout of an image when capturing a bright object. As described above, the capacitive element C1 and the capacitance addition transistor M5 have a function of changing the conversion efficiency from the charge to the voltage in the floating diffusion FD.

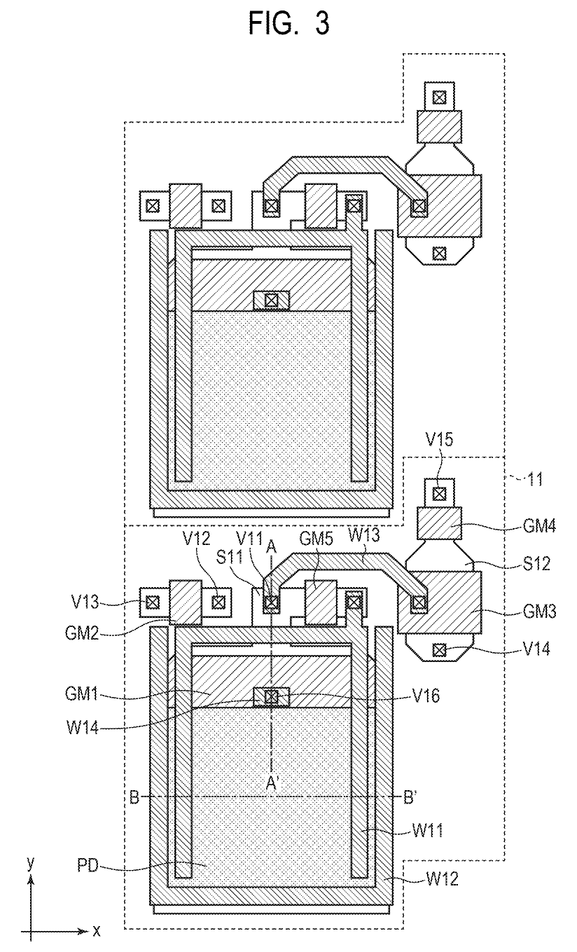

FIG. 3 is a plan view illustrating a configuration example of the pixel 11 according to the present embodiment. FIG. 3 schematically illustrates an arrangement in a plan view of semiconductor regions, gate electrodes, vias, and wirings constituting the photoelectric conversion unit PD, the capacitive element C1, and transistors.

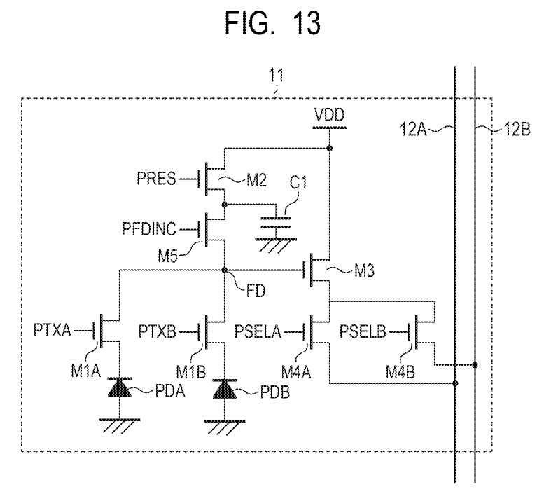

FIG. 3 illustrates an arrangement of gate electrodes GM1 to GM5, an N-type semiconductor region S11, vias V11 to V16, and wirings W11 to W14. The gate electrodes GM1, GM2, GM3, GM4, and GM5 are the gates of the transfer transistor M1, the reset transistor M2, the amplification transistor M3, the selection transistor M4, and the capacitance addition transistor M5, respectively. The N-type semiconductor region S11 is the drain of the transfer transistor M1 and is also the drain (first main electrode) of the capacitance addition transistor M5. The via V11 is electrically connected to the gate electrode GM3 via the wiring W13 (second wiring), and the via V12 is electrically connected to the gate electrode GM3 via a wiring (not illustrated). The connection node of these correspond to the floating diffusion FD illustrated in FIG. 2. Note that the present embodiment is not limited to this arrangement. That is, as illustrated in FIG. 13, the reset transistor M2, the capacitance addition transistor M5, and the floating diffusion FD may be connected in series. This configuration can be realized by a configuration in which the via V12 illustrated in FIG. 3 is connected to the wiring W11 via a wiring (not illustrated). The vias V13 and V14 are connected to the power supply voltage node. The via V15 is connected to the output signal line 12. The gate electrode GM1 is connected to, through the via V16, the wiring W14 (first wiring) to which the control signal PTX is supplied.

The wiring W11 (fourth wiring) is connected to the source (second main electrode) of the capacitance addition transistor M5 through a via. The wiring W12 (third wiring) is connected to a ground line (not illustrated), whereby a predetermined potential is applied to the wiring W12. The wiring W11 and the wiring W12 are arranged in the same layer, and a part of the wiring W11 and a part of the wiring W12 are arranged side by side and close to each other. The wiring W11 and the wiring W12 function as the capacitive element C1 because an interwire capacitance due to electrostatic coupling is generated in the portion where the wirings are close to each other. Note that the wiring W11 and the wiring W12 may be arranged in different layers.

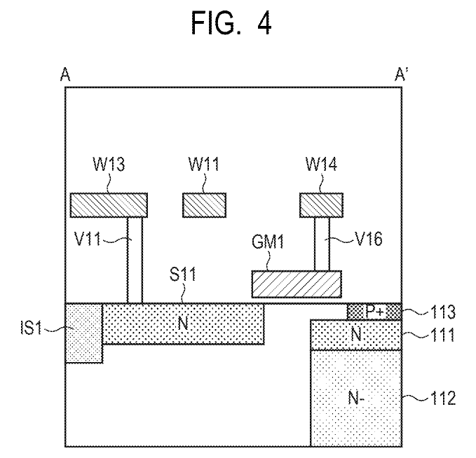

FIG. 4 is a cross-sectional view illustrating a configuration example of the pixel 11 according to the present embodiment. FIG. 4 illustrates a cross section taken along line A-A' in FIG. 3. As illustrated in FIG. 4, an isolation portion IS1, N-type semiconductor regions S11, 111, and 112, and a P-type semiconductor region 113 are arranged in a semiconductor substrate. The gate electrode GM1, the vias V11 and V16, and the wirings W11, W13, and W14 are arranged over the semiconductor substrate.

The isolation portion IS1 is, for example, an element isolation structure formed of a shallow trench isolation (STI), a local oxidation of silicon (LOCOS), or a P-type semiconductor region. The N-type semiconductor region S11 corresponds to the floating diffusion FD illustrated in FIG. 2, and the N-type semiconductor regions 111 and 112 correspond to the photoelectric conversion unit PD illustrated in FIG. 2. The N-type semiconductor region 111 is arranged closer to the front face (face of the wiring layer side) of the semiconductor substrate than the N-type semiconductor region 112. A peak concentration of impurity in the N-type semiconductor region 111 is higher than a peak concentration in impurity in the N-type semiconductor region 112. The P-type semiconductor region 113 suppresses a dark current generated on the front face of the semiconductor substrate.

When the transfer transistor M1 is turned on, the potential of the floating diffusion FD may fluctuate via a parasitic capacitance between the transfer transistor M1 and the floating diffusion FD. A settling time of the potential fluctuation may be a factor that lowers an operation speed of the photoelectric conversion device 1. In particular, when the capacitance addition transistor M5 is off, since the capacitance of the floating diffusion FD is small, a decrease in the operation speed may be remarkable. On the other hand, in the present embodiment, in a plan view, the wiring W11 constituting the capacitive element C1 is arranged between the wiring W13 connected to the floating diffusion FD and the wiring W14 connected to the gate electrode GM1 of the transfer transistor M1. Accordingly, the parasitic capacitance between the transfer transistor M1 and the floating diffusion FD is reduced, and the potential fluctuation of the floating diffusion FD is reduced, so that the decrease in the operation speed of the photoelectric conversion device 1 due to the settling time of the potential fluctuation is improved. Therefore, according to the present embodiment, the operation speed of the photoelectric conversion device 1 can be improved.

As illustrated in FIG. 4, in the present embodiment, the wirings W11, W13, and W14 are arranged in the same layer, but two of the wirings W11, W13, and W14 may be arranged in different layers, or each of the wirings W11, W13, and W14 may be arranged in different layers. However, in a case where the wiring W11 is arranged in the same layer as the wiring W13 and the wiring W14, the wiring W11 can more suitably shield capacitive coupling between the wiring W13 and the wiring W14. Therefore, the parasitic capacitance between the transfer transistor M1 and the floating diffusion FD is suitably reduced. Alternatively, the wiring W11 may be arranged in a layer closer to the semiconductor substrate than the wiring W13 and the wiring W14. As a result, the wiring W11 may shield the capacitive coupling due to a pattern (for example, a gate electrode) below the wiring W13 and the wiring W14, and thus the parasitic capacitance between the transfer transistor M1 and the floating diffusion FD may be suitably reduced.

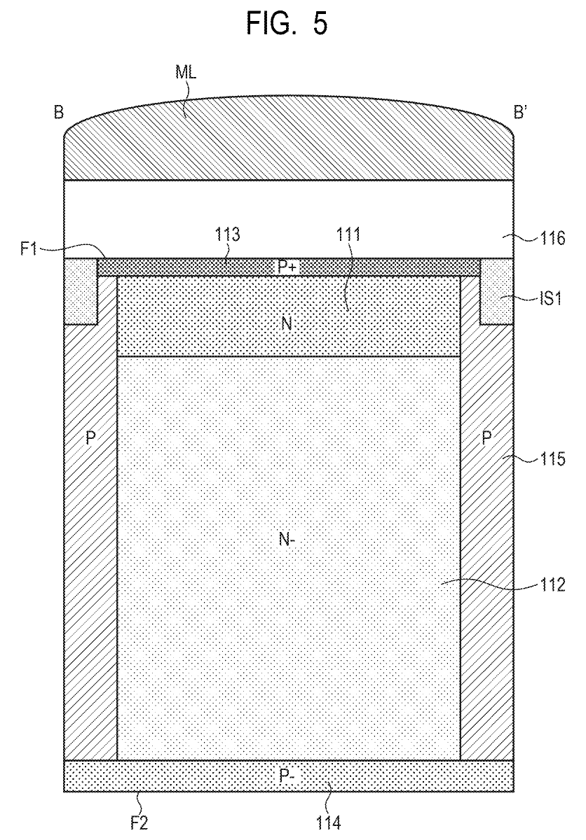

FIG. 5 is a cross-sectional view illustrating a configuration example of the pixel 11 according to the present embodiment. FIG. 5 illustrates a cross section taken along line B-B' in FIG. 3. A wiring layer 116 and a microlens ML are arranged over a first face F1 which is a front face of the semiconductor substrate in which the photoelectric conversion device 1 is formed. A second face F2 opposite to the first face F1 is a back face of the semiconductor substrate. That is, the photoelectric conversion device 1 of the present embodiment is a frontside illumination type that receives light incident from the first face F1. However, the structure of the photoelectric conversion device 1 of the present embodiment may be modified to a backside illumination type that receives light incident from the second face F2. An N-type semiconductor region 111 and an N-type semiconductor region 112 are formed in a portion of the photoelectric conversion unit PD in the semiconductor substrate.

A P-type semiconductor region 113 is arranged at the first face F1 of the semiconductor substrate, and a P-type semiconductor region 114 is arranged at the second face F2 of the semiconductor substrate. A peak concentration of impurity in the P-type semiconductor region 113 is higher than a peak concentration of impurity in the P-type semiconductor region 114. The P-type semiconductor region 113 suppresses a dark current generated on the first face F1, and the P-type semiconductor region 114 suppresses a dark current generated on the second face F2.

P-type semiconductor region 115 and the isolation portion IS1 are arranged outside the N-type semiconductor regions 111 and 112. The P-type semiconductor region 115 and the isolation portion IS1 electrically isolate adjacent pixels from each other.

As described above, the photoelectric conversion device 1 of the present embodiment has a wiring structure capable of reducing the parasitic capacitance between the transfer transistor M1 and the floating diffusion FD. Therefore, according to the present embodiment, the photoelectric conversion device 1 capable of improving the operation speed is provided.

### Second Embodiment

In the present embodiment, a modification in which the pixel 11 includes two photoelectric conversion units and two transfer transistors will be described. In the present embodiment, description of elements common to those of the first embodiment may be omitted or simplified.

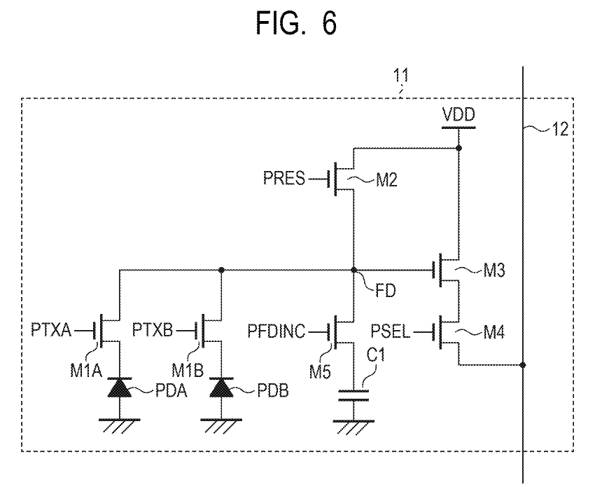

FIG. 6 is a circuit diagram illustrating a configuration example of the pixel 11 according to the present embodiment. The pixel 11 of the present embodiment includes two photoelectric conversion units PDA and PDB (first photoelectric conversion unit and second photoelectric conversion unit) and two transfer transistors M1A and M1B (first transfer transistor and second transfer transistor). This point of the pixel 11 of the present embodiment is different from the pixel 11 of FIG. 2 of the first embodiment. Anodes of the photoelectric conversion units PDA and PDB are connected to the ground line having the ground potential. A cathode of the photoelectric conversion unit PDA is connected to a source of the transfer transistor M1A, and a cathode of the photoelectric conversion unit PDB is connected to a source of the transfer transistor M1B. Drains of the transfer transistors M1A and M1B are connected to the source of the reset transistor M2, the drain of the capacitance addition transistor M5, and the gate of the amplification transistor M3. A connection node between the drains of the transfer transistors M1A and M1B, the source of the reset transistor M2, the drain of the capacitance addition transistor M5, and the gate of the amplification transistor M3 is the floating diffusion FD.

The vertical scanning circuit 20 supplies a control signal PTXA to a gate of the transfer transistor M1A via one signal line constituting the scanning line 13. When the transfer transistor M1A is turned on according to the control signal PTXA, charges accumulated in the photoelectric conversion unit PDA is transferred to the floating diffusion FD. Further, the vertical scanning circuit 20 supplies a control signal PTXB to a gate of the transfer transistor M1B via another signal line constituting the scanning line 13. When the transfer transistor M1B is turned on according to the control signal PTXB, charges accumulated in the photoelectric conversion unit PDB is transferred to the floating diffusion FD.

As described above, in the present embodiment, the two photoelectric conversion units PDA and PDB share the reset transistor M2, the amplification transistor M3, the selection transistor M4, and the capacitance addition transistor M5. That is, the number of transistors per photoelectric conversion unit (the ratio of the number of transistors to the number of photoelectric conversion units) is reduced. Thus, for example, the pixel 11 can be miniaturized.

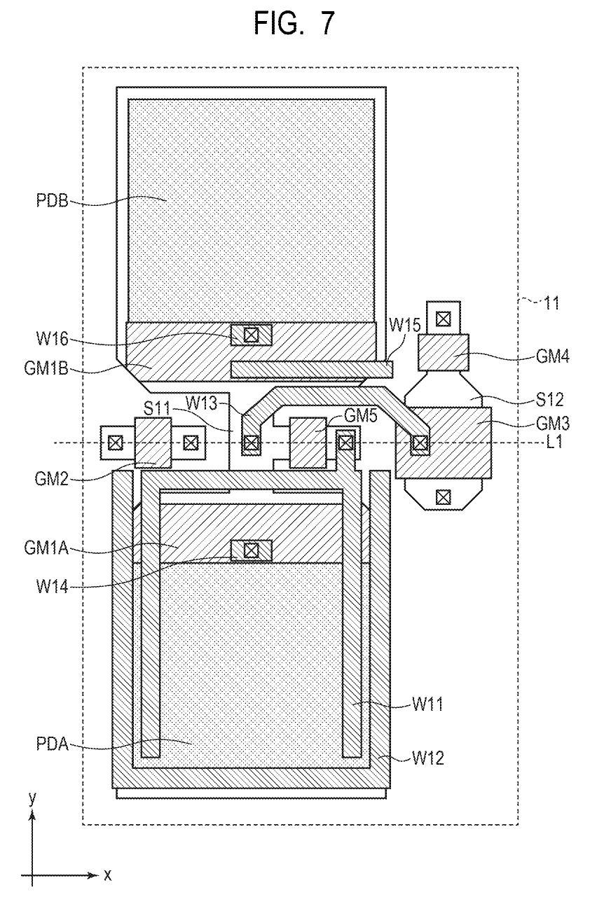

FIG. 7 is a plan view illustrating a configuration example of the pixel 11 according to the present embodiment. FIG. 7 schematically illustrates an arrangement of semiconductor regions, gate electrodes, vias, and wirings constituting the photoelectric conversion units PDA and PDB, the capacitive element C1, and the transistors in a plan view. A gate electrode GM1A is the gate of the transfer transistor M1A, and a gate electrode GM1B is the gate of the transfer transistor M1B. The N-type semiconductor region S11 is the drain of the transfer transistor M1A and the drain of the transfer transistor M1B, and is shared by the transfer transistor M1A and the transfer transistor M1B. The transfer transistor M1A and the transfer transistor M1B are arranged line-symmetrically with respect to a line segment L1 parallel to the x direction, the line segment L1 passing between the gate electrode GM1A and the gate electrode GM1B. That is, the gate electrode GM1A and the gate electrode GM1B are also arranged line-symmetrically with respect to the line segment L1. However, the transfer transistor M1A and the transfer transistor M1B may be arranged asymmetrically.

The gate electrode GM1A is connected to the wiring W14 to which the control signal PTXA is supplied through a via, and the gate electrode GM1B is connected to a wiring W16 (fifth wiring) to which the control signal PTXB is supplied through a via. A wiring W15 (sixth wiring) is arranged between the wiring W14 and the wiring W16 in a plan view, and is connected to the power supply voltage node.

In the present embodiment, as in the first embodiment, the wiring W11 configuring the capacitive element C1 is arranged between the wiring W13 connected to the floating diffusion FD and the wiring W14 connected to the gate electrode GM1A of the transfer transistor M1A. Therefore, as in the first embodiment, the parasitic capacitance between the transfer transistor M1A and the floating diffusion FD is reduced, and the operation speed of the photoelectric conversion device 1 can be improved.

The wiring W11 is not arranged between the wiring W13 and the wiring W16 connected to the gate electrode GM1B of the transfer transistor M1B. However, in the present embodiment, the wiring W15 is arranged between the wiring W13 and the wiring W16. Accordingly, the parasitic capacitance between the transfer transistor M1B and the floating diffusion FD is reduced, and the operation speed of the photoelectric conversion device 1 can be improved.

Also in the present embodiment, similarly to the first embodiment, the photoelectric conversion device 1 capable of improving the operation speed is provided.

### Third Embodiment

In the present embodiment, a modification of the wiring between the transfer transistor M1B and the floating diffusion FD will be described. In the present embodiment, description of elements common to the first embodiment and the second embodiment may be omitted or simplified.

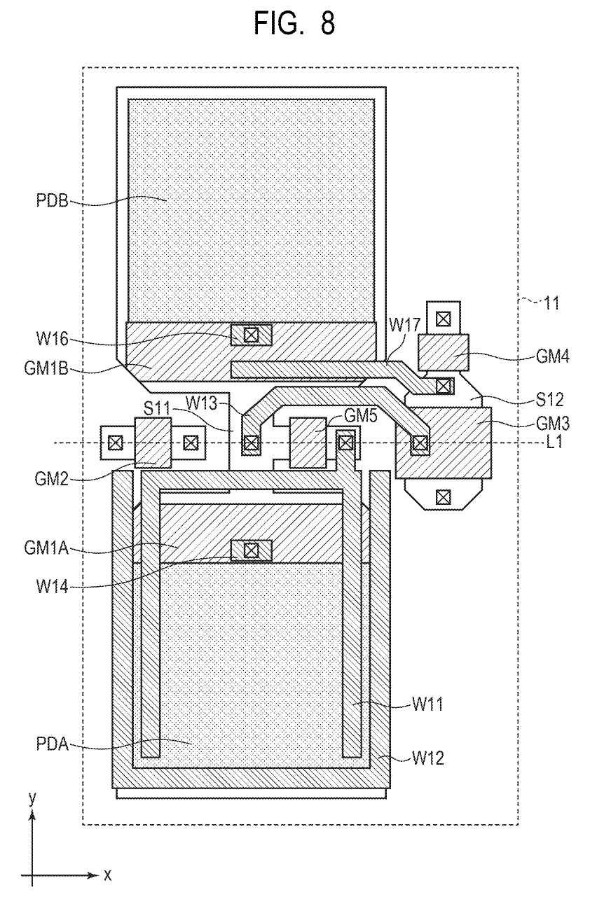

FIG. 8 is a plan view illustrating a configuration example of the pixel 11 according to the present embodiment. In FIG. 8, a wiring W17 is arranged instead of the wiring W15 in FIG. 7. The wiring W17 is connected to an N-type semiconductor region S12 through a via. The N-type semiconductor region S12 is the source of the amplification transistor M3 and is also the drain of the selection transistor M4.

In the present embodiment, the wiring W17 is further arranged between the wiring W13 and the wiring W16 connected to the gate electrode GM1B of the transfer transistor M1B. Accordingly, as in the second embodiment, the parasitic capacitance between the transfer transistor M1B and the floating diffusion FD is reduced, and the operation speed of the photoelectric conversion device 1 can be improved.

Also in the present embodiment, similarly to the first embodiment and the second embodiment, the photoelectric conversion device 1 capable of improving the operation speed is provided.

### Fourth Embodiment

In the present embodiment, a modification in which the pixel 11 includes two selection transistors will be described. In the present embodiment, description of elements common to the first to third embodiments may be omitted or simplified.

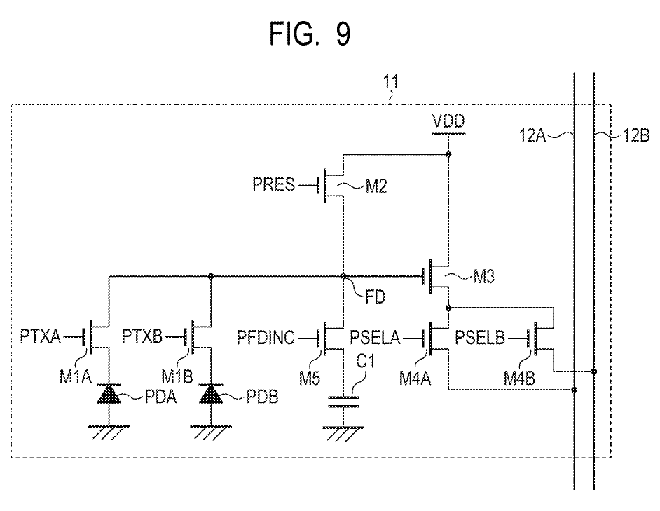

FIG. 9 is a circuit diagram illustrating a configuration example of the pixel 11 according to the present embodiment. The pixel 11 of the present embodiment has two selection transistors M4A and M4B (first selection transistor and second selection transistor). This point of the pixel 11 of the present embodiment is different from the pixel 11 of FIG. 6 of the second embodiment. Further, in the photoelectric conversion device 1 of the present embodiment, two output signal lines 12A and 12B (first output signal line and second output signal line) are arranged for each column.

Drains of the selection transistors M4A and M4B are connected to the source of the amplification transistor M3. A source of the selection transistor M4A is connected to the output signal line 12A, and a source of the selection transistor M4B is connected to the output signal line 12B.

The vertical scanning circuit 20 supplies a control signal PSELA to a gate of the selection transistor M4A via one signal line constituting the scanning line 13. When the selection transistor M4A is turned on according to the control signal PSELA, a signal is output from the amplification transistor M3 in the corresponding row to the output signal line 12A. In addition, the vertical scanning circuit 20 supplies a control signal PSELB to a gate of the selection transistor M4B via another signal line constituting the scanning line 13. When the selection transistor M4B is turned on according to the control signal PSELB, a signal is output from the amplification transistor M3 in the corresponding row to the output signal line 12B.

As described above, in the present embodiment, signals can be output from one pixel 11 to the two output signal lines 12A and 12B. Thus, a plurality of signal readout methods can be performed in parallel. For example, a readout method of outputting a signal from each pixel via the output signal line 12A and a readout method of adding and outputting signals of a plurality of pixels of the same color via the output signal line 12B can be performed in parallel. In this case, since the time required to read out the signals can be reduced, the speed of the imaging operation can be increased.

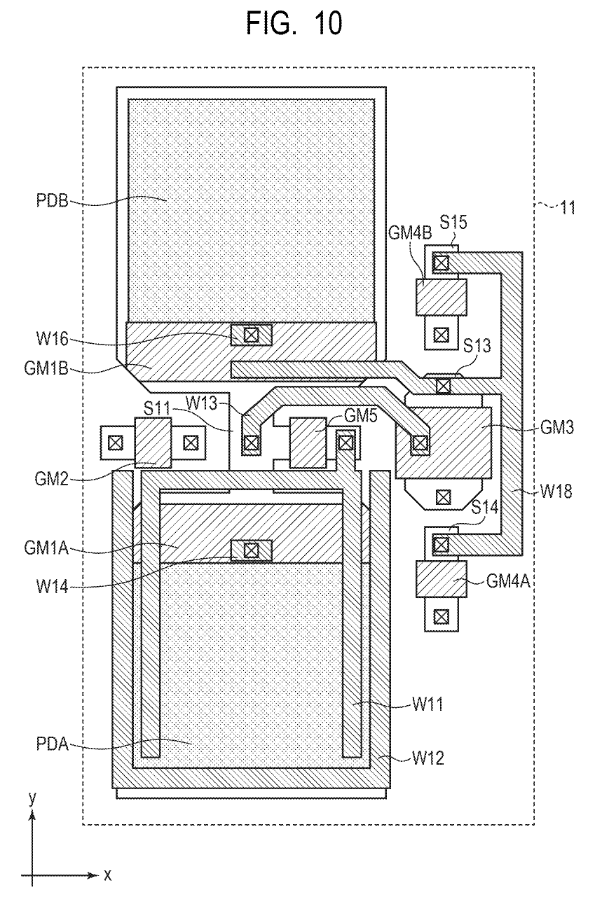

FIG. 10 is a plan view illustrating a configuration example of the pixel 11 according to the present embodiment. FIG. 10 schematically illustrates an arrangement of semiconductor regions, gate electrodes, vias, and wirings constituting the photoelectric conversion units PDA and PDB, the capacitive element C1, and the transistors in a plan view. A gate electrode GM4A is the gate of the selection transistor M4A, and a gate electrode GM4B is the gate of the selection transistor M4B. An N-type semiconductor region S13 is the source of the amplification transistor M3, an N-type semiconductor region S14 is the drain of the selection transistor M4A, and an N-type semiconductor region S15 is the drain of the selection transistor M4B. The N-type semiconductor regions S13, S14, and S15 are connected to each other through vias and a wiring W18. Further, as in the second embodiment and the third embodiment, since a part of the wiring W18 is arranged between the wiring W13 and the wiring W16, the same effect as in the second embodiment and the third embodiment can be obtained.

Also in the present embodiment, similarly to the first embodiment to the third embodiment, the photoelectric conversion device 1 capable of improving the operation speed is provided.

### Fifth Embodiment

In the present embodiment, a modification in which the source of the amplification transistor M3 is configured by two N-type semiconductor regions in the configuration of the fourth embodiment will be described. In the present embodiment, description of elements common to the first to fourth embodiments may be omitted or simplified.

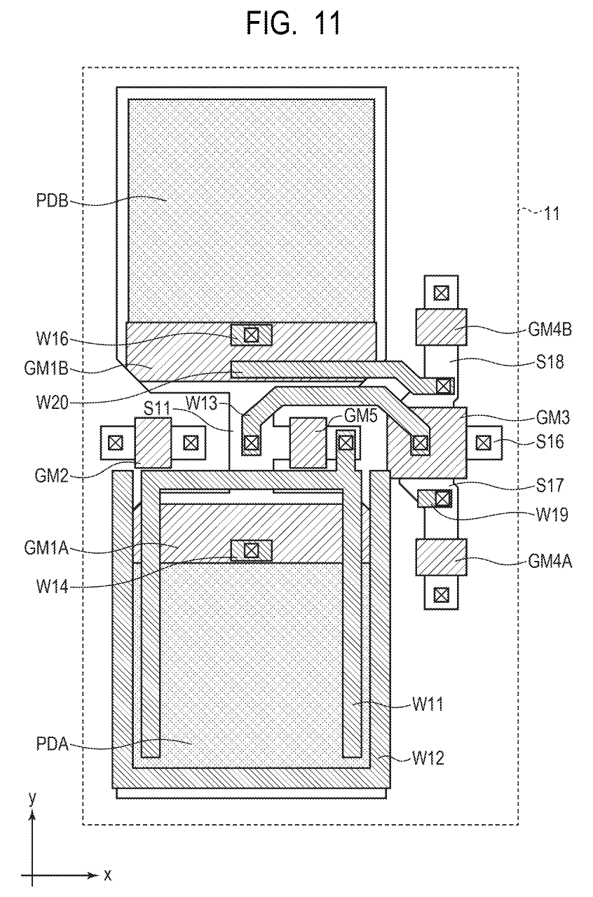

FIG. 11 is a plan view illustrating a configuration example of the pixel 11 according to the present embodiment. In FIG. 11, wirings W19 and W20 are arranged instead of the wiring W18 in FIG. 10, and N-type semiconductor regions S16, S17, and S18 are arranged instead of the N-type semiconductor regions S13, S14, and S15 in FIG. 10. The N-type semiconductor region S17 (first semiconductor region) serves as the source of the amplification transistor M3 and the drain of the selection transistor M4A. The N-type semiconductor region S17 is connected to the wiring W19 through a via. The N-type semiconductor region S18 (second semiconductor region) serves as the source of the amplification transistor M3 and the drain of the selection transistor M4B. The N-type semiconductor region S18 is connected to the wiring W20 through a via. The N-type semiconductor region S16 is the drain of the amplification transistor M3. The wiring W19 and the wiring W20 are connected to each other by an upper layer wiring (not illustrated). Since a part of the wiring W20 is arranged between the wiring W13 and the wiring W16 as in the second embodiment and the third embodiment, the same effects as in the second embodiment to the fourth embodiment can be obtained.

Further, in the present embodiment, unlike the fourth embodiment, a wiring that connects the source of the amplification transistor M3 and the drains of the selection transistors M4A and M4B is not necessary. Therefore, the wiring density in the pixel 11 is reduced, and the possibility that an unintended short circuit occurs between the wirings in the manufacturing process of the wirings is reduced. Therefore, the yield of the photoelectric conversion device 1 can be improved.

Also in the present embodiment, as in the first to fourth embodiments, the photoelectric conversion device 1 capable of improving signal quality is provided.

### Sixth Embodiment

In the present embodiment, a modification in which the source of the reset transistor M2 and the drain of the capacitance addition transistor M5 are constituted by one semiconductor region will be described. In the present embodiment, description of elements common to the first to fifth embodiments may be omitted or simplified.

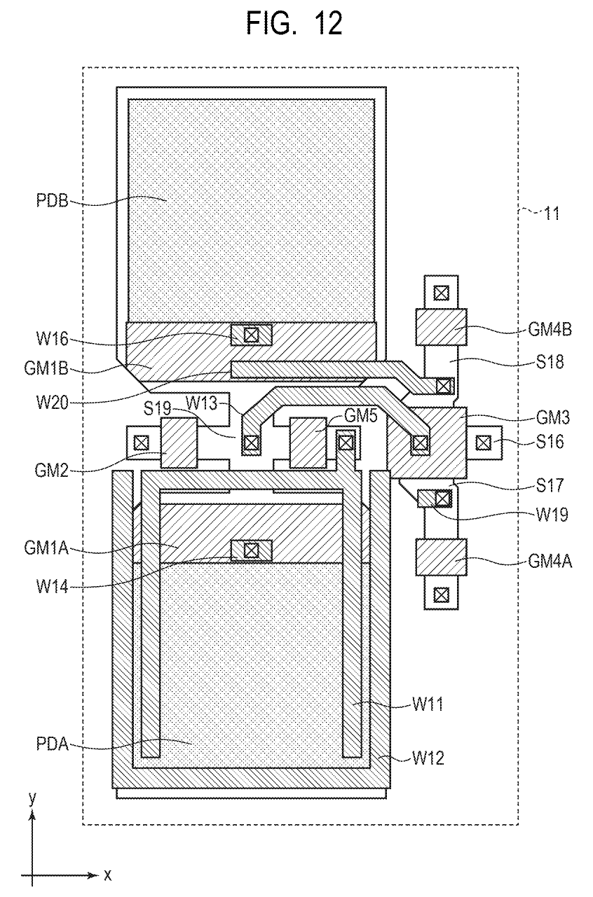

FIG. 12 is a plan view illustrating a configuration example of the pixel 11 according to the present embodiment. In FIG. 12, an N-type semiconductor region S19 (third semiconductor region) serves as the source of the reset transistor M2 and the drain of the capacitance addition transistor M5, and functions as the floating diffusion FD.

In the configuration of the fifth embodiment illustrated in FIG. 11, an isolation portion is arranged between the source of the reset transistor M2 and the drain of the capacitance addition transistor M5. However, in the present embodiment, since this isolation portion is unnecessary, the area efficiency is improved, and the pixel 11 can be miniaturized.

Also in the present embodiment, similarly to the first embodiment to the fifth embodiment, the photoelectric conversion device 1 capable of improving the signal quality is provided.

### Seventh Embodiment

In the present embodiment, a modification related to a connection relationship among the reset transistor M2, the capacitance addition transistor M5, and the capacitive element C1 will be described. In the present embodiment, description of elements common to the first to sixth embodiments may be omitted or simplified.

FIG. 13 is a circuit diagram illustrating a configuration example of the pixel 11 according to the present embodiment. Differences from FIG. 9 will be described. The source of the capacitance addition transistor M5 is connected to the drains of the transfer transistors M1A and M1B and the gate of the amplification transistor M3. A connection node between the drains of the transfer transistors M1A and M1B, the source of the capacitance addition transistor M5, and the gate of the amplification transistor M3 is the floating diffusion FD. The drain of the capacitance addition transistor M5 is connected to the first terminal of the capacitive element C1 and the source of the reset transistor. The second terminal of the capacitive element C1 is connected to the ground line having the ground potential.

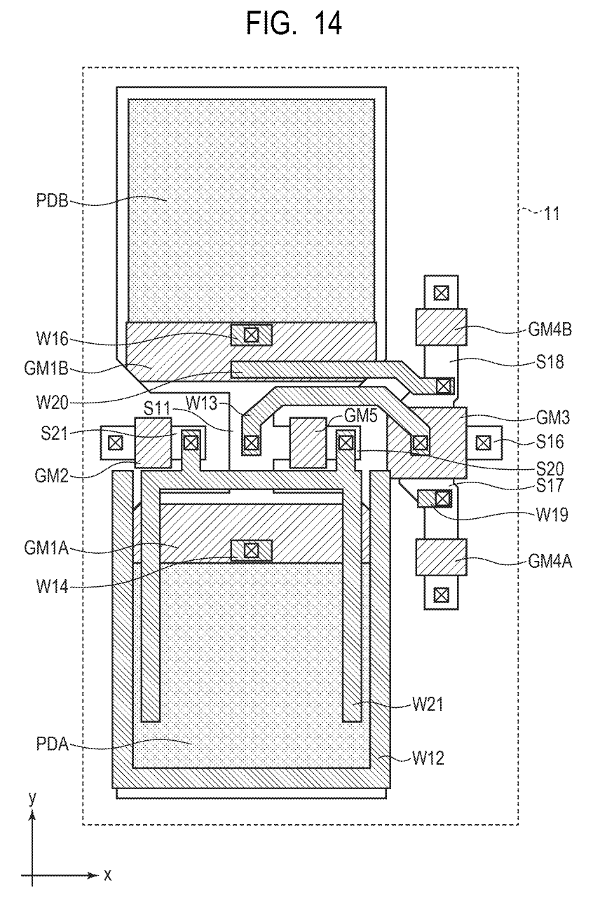

FIG. 14 is a plan view illustrating a configuration example of the pixel 11 according to the present embodiment. In FIG. 14, a wiring W21 is arranged instead of the wiring W11 in FIG. 11. The wiring W21 is connected to an N-type semiconductor region S21 that is the source of the reset transistor M2 and an N-type semiconductor region S20 that is the drain of the capacitance addition transistor M5 through the vias. A part of the wiring W21 and a part of the wiring W12 are arranged side by side and close to each other, and function as the capacitive element C1.

By arranging the wiring W21 as described above, the parasitic capacitance between the gate electrode GM2 of the reset transistor and the N-type semiconductor region S11 can be reduced. As a result, the capacitance of the floating diffusion FD is reduced, and the conversion efficiency from the charge to the voltage in the floating diffusion FD can be increased.

Also in the present embodiment, as in the first to sixth embodiments, the photoelectric conversion device 1 capable of improving signal quality is provided.

### Eighth Embodiment

In the present embodiment, a modification in which the pixel 11 includes four photoelectric conversion units and four transfer transistors will be described. Further, in the present embodiment, the microlens ML is arranged not at the first face F1 side but at the second face F2 side. In the present embodiment, description of elements common to the first to seventh embodiments may be omitted or simplified.

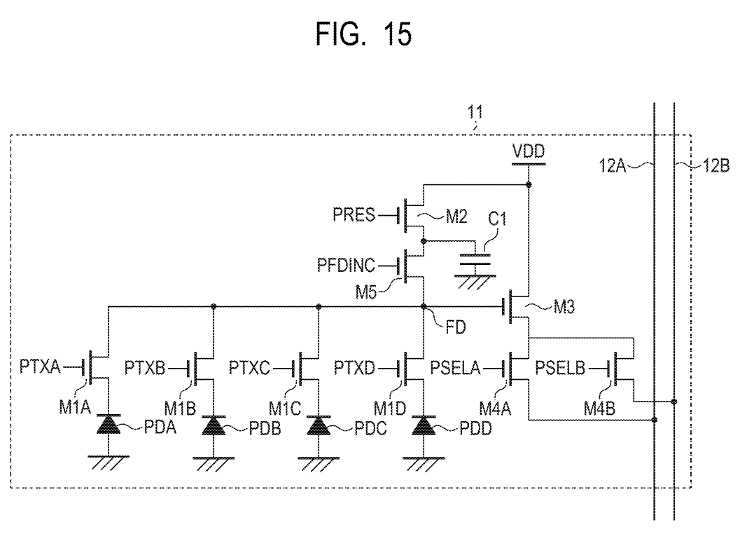

FIG. 15 is a circuit diagram illustrating a configuration example of the pixel 11 according to the present embodiment. The pixel 11 of the present embodiment includes four photoelectric conversion units PDA, PDB, PDC, and PDD and four transfer transistors M1A, M1B, M1C, and M1D. This point of the pixel 11 of the present embodiment is different from the pixel 11 of FIG. 13 of the seventh embodiment. Hereinafter, the photoelectric conversion units PDC and PDD and the transfer transistors M1C and M1D added to FIG. 13 of the seventh embodiment will be mainly described.

Anodes of the photoelectric conversion units PDC and PDD are connected to the ground line having the ground potential. A cathode of the photoelectric conversion unit PDC (third photoelectric conversion unit) is connected to a source of the transfer transistor M1C (third transfer transistor), and a cathode of the photoelectric conversion unit PDD is connected to a source of the transfer transistor M1D. Drains of the transfer transistors M1C and M1D are connected to the source of the capacitance addition transistor M5 and the gate of the amplification transistor M3. A connection node between the drains of the transfer transistors M1A, M1B, M1C, and M1D, the source of the capacitance addition transistor M5, and the gate of the amplification transistor M3 is the floating diffusion FD.

The vertical scanning circuit 20 supplies a control signal PTXC to a gate of the transfer transistor M1C via one signal line constituting the scanning line 13. When the transfer transistor M1C is turned on according to the control signal PTXC, charges accumulated in the photoelectric conversion unit PDC is transferred to the floating diffusion FD. Further, the vertical scanning circuit 20 supplies a control signal PTXD to a gate of the transfer transistor M1D via another signal line constituting the scanning line 13. When the transfer transistor M1D is turned on according to the control signal PTXD, charges accumulated in the photoelectric conversion unit PDD is transferred to the floating diffusion FD.

As described above, in the present embodiment, the four photoelectric conversion units PDA, PDB, PDC, and PDD share the reset transistor M2, the amplification transistor M3, the selection transistors M4A and M4B, and the capacitance addition transistor M5. That is, the number of transistors per photoelectric conversion unit is further reduced.

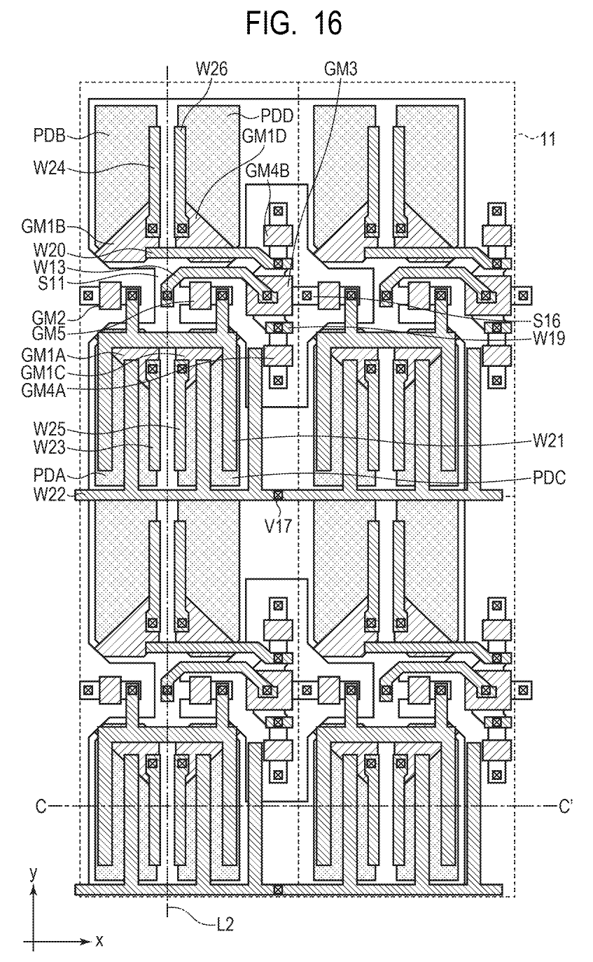

FIG. 16 is a plan view illustrating a configuration example of the pixel 11 according to the present embodiment. FIG. 16 schematically illustrates an arrangement of semiconductor regions, gate electrodes, vias, and wirings constituting the photoelectric conversion units PDA, PDB, PDC, and PDD, the capacitive element C1, and the transistors in a plan view. A gate electrode GM1C is the gate of the transfer transistor M1C, and a gate electrode GM1D is the gate of the transfer transistor M1D. The N-type semiconductor region S11 is the drains of the transfer transistors M1A, M1B, M1C, and M1D, and is shared by the four transfer transistors M1A, M1B, M1C, and M1D. A via V17 connects a P-type semiconductor region isolating the photoelectric conversion units and a wiring W22, and supplies the ground potential to the P-type semiconductor region.

The gate electrode GM1A is connected to a wiring W23 to which the control signal PTXA is supplied through a via, and the gate electrode GM1B is connected to a wiring W24 to which the control signal PTXB is supplied through a via. The gate electrode GM1C is connected to a wiring W25 to which the control signal PTXC is supplied through a via, and the gate electrode GM1D is connected to a wiring W26 to which the control signal PTXD is supplied through a via. The wiring W21 is arranged between the wiring W23 and the wiring W13 and between the wiring W25 and the wiring W13 in a plan view. The wiring W20 is arranged between the wiring W24 and the wiring W13 and between the wiring W26 and the wiring W13 in a plan view. As a result, the parasitic capacitance between each transfer transistor and the floating diffusion FD can be reduced.

The photoelectric conversion unit PDA and the photoelectric conversion unit PDC are arranged line-symmetrically with respect to a line segment L2 parallel to the y direction. Accordingly, a focus detection of a phase difference detection method in the x direction can be performed by a signal based on charges accumulated in the photoelectric conversion unit PDA and a signal based on charges accumulated in the photoelectric conversion unit PDC. The photoelectric conversion unit PDB and the photoelectric conversion unit PDD are arranged line-symmetrically with respect to the line segment L2. Accordingly, the focus detection of the phase difference detection method in the x direction can be performed by a signal based on charges accumulated in the photoelectric conversion unit PDB and a signal based on charges accumulated in the photoelectric conversion unit PDD.

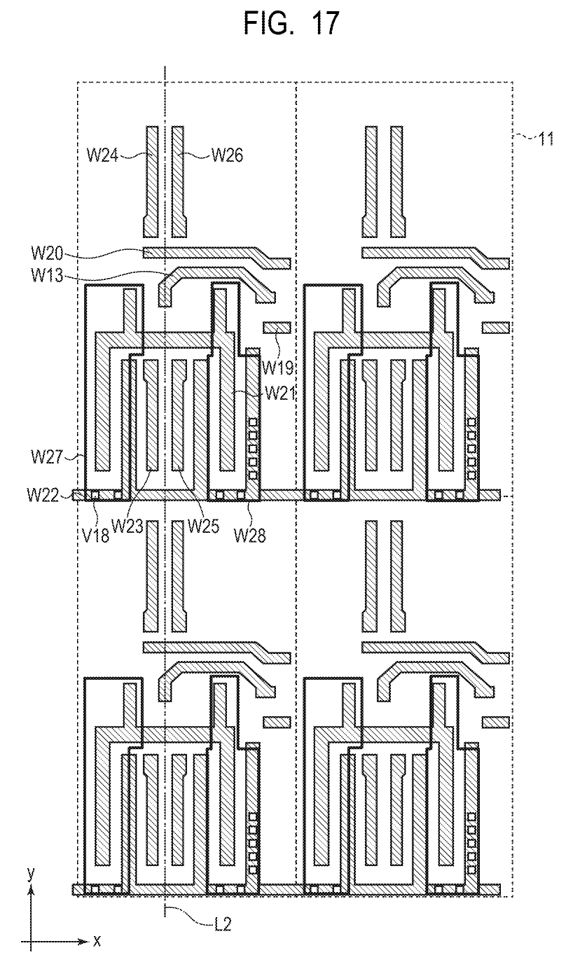

FIG. 17 is a plan view illustrating a configuration example of the pixel 11 according to the present embodiment. FIG. 17 schematically illustrates an arrangement in a plan view of the wiring W13 and the wirings W19 to W26, wirings W27 and W28 arranged in an upper layer than the wiring W13 and the wirings W19 to W26, and a via V18 connecting these two layers of wirings.

The wiring W27 is arranged so as to overlap at least a part of the wiring W21 in a plan view. Similarly, the wiring W28 is also arranged so as to overlap at least a part of the wiring W21 in a plan view. The wirings W27 and W28 are connected to the wiring W22 through the via V18, and thus the ground potential is supplied to the wirings W27 and W28. Therefore, since an interwire capacitance due to electrostatic coupling is generated between the wiring W21 and the wirings W27 and W28, the group (third wiring) including the wirings W21, W27, and W28 functions as a part of the capacitive element C1.

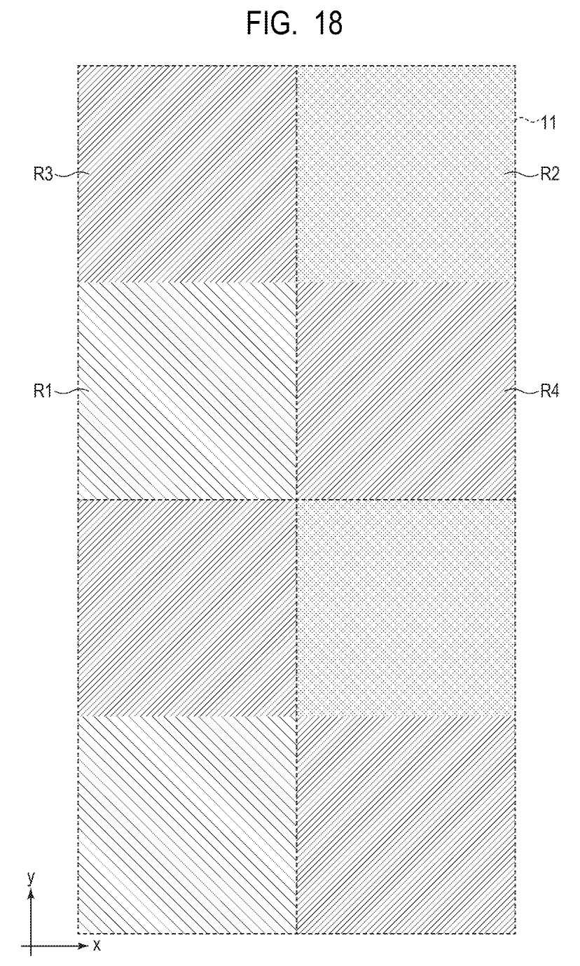

FIG. 18 is a plan view illustrating an arrangement example of color filters according to the present embodiment. FIG. 18 schematically illustrates an example of an arrangement method of color filters of three colors arranged corresponding to the four pixels 11 illustrated in FIGS. 16 and 17. In FIG. 18, a red color filter is arranged in a region R1. A blue color filter is arranged in a region R2. Green color filters are arranged in a region R3 and a region R4, respectively. That is, the photoelectric conversion unit in the region R1 has sensitivity to red (first wavelength) light, the photoelectric conversion unit (fourth photoelectric conversion unit) in the region R2 has sensitivity to blue (second wavelength) light, and the photoelectric conversion units in the regions R3 and R4 have sensitivity to green light. Here, as can be understood by comparing FIG. 17 and FIG. 18, the wiring density in the region R1 that receives light of a relatively long wavelength is higher than the wiring density in the region R2 that receives light of a relatively short wavelength.

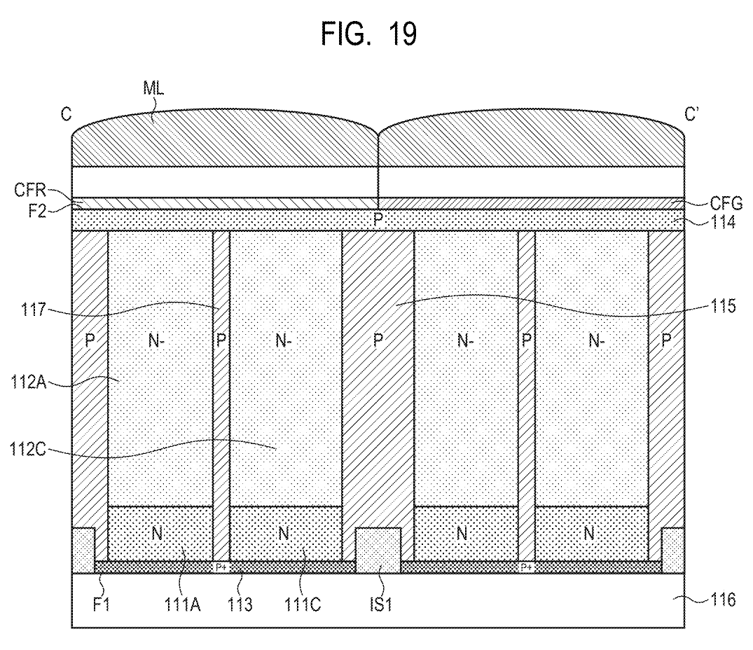

FIG. 19 is a cross-sectional view illustrating a configuration example of the pixel 11 according to the present embodiment. FIG. 19 illustrates a cross section taken along line C-C' in FIG. 16. A wiring layer 116 is arranged over a first face F1 which is a front face of the semiconductor substrate in which the photoelectric conversion device 1 is formed. A second face F2 opposite to the first face F1 is a back face of the semiconductor substrate. A red color filter CFR, a green color filter CFG, and a microlens ML are arranged over the second face F2. That is, the photoelectric conversion device 1 of the present embodiment is a backside illumination type that receives light incident from the second face F2.

N-type semiconductor regions 111A and 111C and N-type semiconductor regions 112A and 112C are formed in portions of the photoelectric conversion units PDA and PDC in the semiconductor substrate. The N-type semiconductor region 111A is arranged closer to the first face F1 than the N-type semiconductor region 112A, and the N-type semiconductor region 111C is arranged closer to the first face F1 than the N-type semiconductor region 112C. Peak concentrations of impurity in the N-type semiconductor regions 111A and 111C are higher than peak concentrations of impurity in the N-type semiconductor regions 112A and 112C. A P-type semiconductor region 117 is arranged between the N-type semiconductor region 111A and the N-type semiconductor region 111C and between the N-type semiconductor region 112A and the N-type semiconductor region 112C. The P-type semiconductor region 117 is an isolation portion that separates the N-type semiconductor region 111A and the N-type semiconductor region 111C and separates the N-type semiconductor region 112A and the N-type semiconductor region 112C.

A common microlens ML is arranged over each of the photoelectric conversion units PDA and PDC, and light that has passed through different pupil regions of the optical system enters each of the photoelectric conversion units PDA and PDC. In addition, another common microlens is arranged over the photoelectric conversion units PDB and PDD, and light that has passed through different pupil regions of the optical system enters each of the photoelectric conversion units PDB and PDD. With these configurations, signals that can be suitably used for the focus detection by the phase difference detection method are generated.

In the present embodiment, the backside illumination type in which the photoelectric conversion device receives incident light from the second face F2 different from the first face F1 on which the wiring layer 116 is arranged is employed. Accordingly, the incident light to the second face F2 enters the photoelectric conversion units PDA, PDB, PDC, and PDD without being reflected by the wiring in the wiring layer 116, and signals corresponding to the incident light are generated. Therefore, the sensitivity of the photoelectric conversion units PDA, PDB, PDC, and PDD can be improved.

In the present embodiment, the wiring density in the region R1 in which the red color filter is arranged is higher than the wiring density in the region R2 in which the blue color filter is arranged. In general, in a visible light wavelength range, light having a longer wavelength penetrates deeper into a semiconductor substrate such as silicon. Therefore, a loss may occur due to transmission of light of a long wavelength through a face opposite to the incident face. In the present embodiment, since the wiring layer 116 on the first face F1 side of the region R1 in which the red color filter is arranged has a high wiring density, the incident light transmitted through the semiconductor substrate can be reflected to the photoelectric conversion portion side, and thus, in particular, the sensitivity of the red pixel can be further improved.

Also in the present embodiment, as in the first to seventh embodiments, the photoelectric conversion device 1 capable of improving signal quality is provided.

### Ninth Embodiment

In the present embodiment, a modification in which the pixel 11 includes eight photoelectric conversion units and eight transfer transistors will be described. In the present embodiment, description of elements common to the first to seventh embodiments may be omitted or simplified.

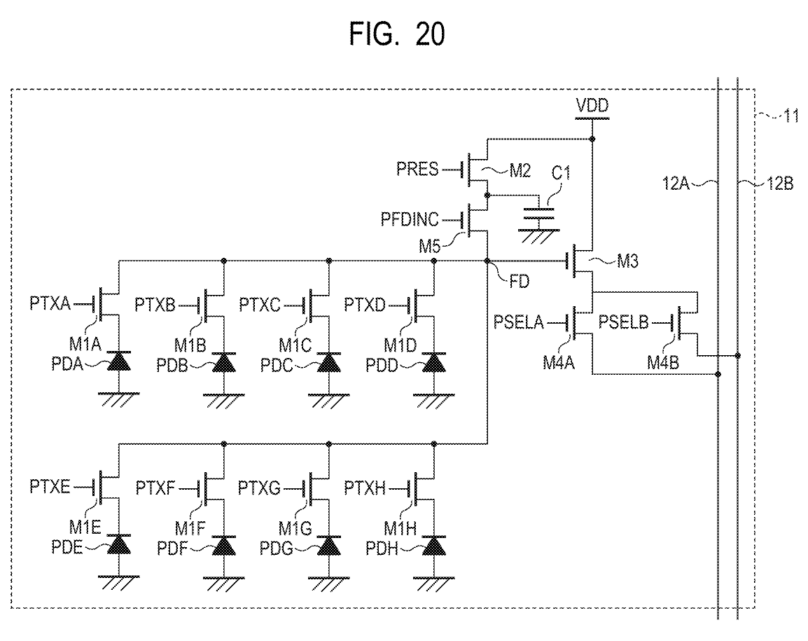

FIG. 20 is a circuit diagram illustrating a configuration example of the pixel 11 according to the present embodiment. The pixel 11 of the present embodiment includes eight photoelectric conversion units PDA, PDB, PDC, PDD, PDE, PDF, PDG, and PDH and eight transfer transistors M1A, M1B, M1C, M1D, M1E, M1F, M1G, and M1H. This point in the pixel 11 of the present embodiment is different from the pixel 11 of FIG. 15 of the eighth embodiment. Hereinafter, the photoelectric conversion units PDE, PDF, PDG, and PDH and the transfer transistors M1E, M1F, M1G, and M1H, which are added to FIG. 15 of the eighth embodiment, will be mainly described.

Anodes of the photoelectric conversion units PDE, PDF, PDG, and PDH are connected to the ground line having the ground potential. Cathodes of the photoelectric conversion units PDE, PDF, PDG, and PDH (fourth photoelectric conversion units) are connected to sources of the transfer transistors M1E, M1F, M1G, and M1H (fourth transfer transistors), respectively. Drains of the transfer transistors M1E, M1F, M1G, and M1H are connected to the source of the capacitance addition transistor M5 and the gate of the amplification transistor M3. A connection node between the drains of the transfer transistors M1A, M1B, M1C, M1D, M1E, M1F, M1G, and M1H, the source of the capacitance addition transistor M5, and the gate of the amplification transistor M3 is the floating diffusion FD.

The vertical scanning circuit 20 supplies control signals PTXE, PTXF, PTXG, and PTXH to gates of the transfer transistors M1E, M1F, M1G, and M1H, respectively, via signal lines constituting the scanning lines 13. When the transfer transistors M1E, M1F, M1G, and M1H are turned on according to the control signals PTXE, PTXF, PTXG, and PTXH, the charges accumulated in the photoelectric conversion units PDE, PDF, PDG, and PDH are transferred to the floating diffusion FD, respectively.

As described above, in the present embodiment, the eight photoelectric conversion units PDA, PDB, PDC, PDD, PDE, PDF, PDG, and PDH share the reset transistor M2, the amplification transistor M3, the selection transistors M4A and M4B, and the capacitance addition transistor M5. That is, the number of transistors per photoelectric conversion unit is further reduced.

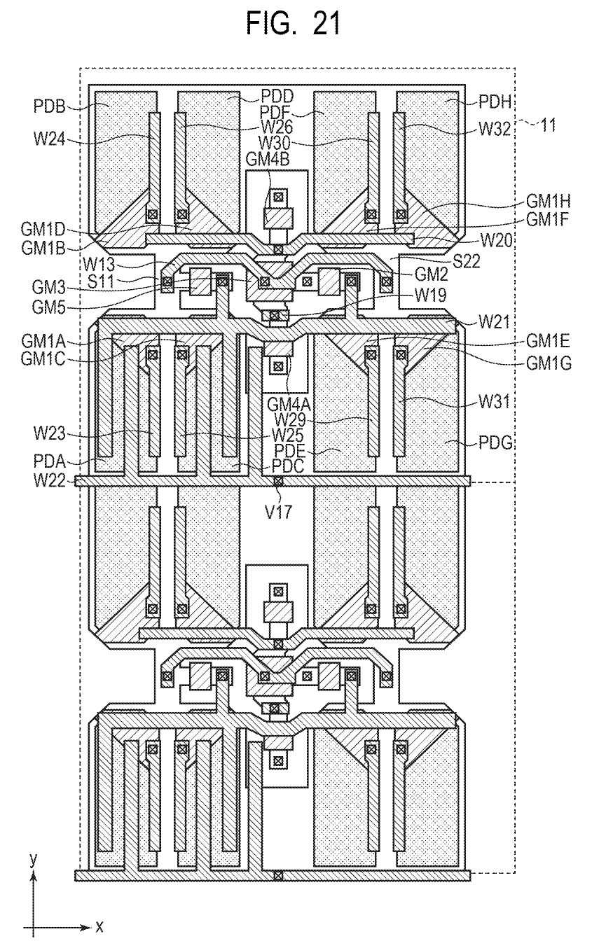

FIG. 21 is a plan view illustrating a configuration example of the pixel 11 according to the present embodiment. FIG. 21 schematically illustrates an arrangement of semiconductor regions, gate electrodes, vias, and wirings constituting the photoelectric conversion units PDE, PDF, PDG, and PDH, the capacitive element C1, and the transistors in a plan view. Gate electrodes GM1E, GM1F, GM1G, and GM1H are the gates of the transfer transistors M1E, M1F, M1G, and M1H, respectively. The N-type semiconductor region S11 is the drains of the transfer transistors M1A, M1B, M1C, and M1D, and is shared by the four transfer transistors M1A, M1B, M1C, and M1D. An N-type semiconductor region S22 is the drains of the transfer transistors M1E, M1F, M1G, and M1H, and is shared by the four transfer transistors M1E, M1F, M1G, and M1H. The N-type semiconductor region S11 and the N-type semiconductor region S22 are connected to each other through vias and the wiring W13.

The gate electrode GM1E is connected to a wiring W29 to which the control signal PTXE is supplied through a via, and the gate electrode GM1F is connected to a wiring W30 to which the control signal PTXF is supplied through a via. The gate electrode GM1G is connected to a wiring W31 to which the control signal PTXG is supplied through a via, and the gate electrode GM1H is connected to a wiring W32 to which the control signal PTXH is supplied through a via. The wirings W20 and W21 extend from a region in which the photoelectric conversion units PDA, PDB, PDC, and PDD are arranged to a region in which the photoelectric conversion units PDE, PDF, PDG, and PDH are arranged. The wiring W21 is arranged between the wiring W29 and the wiring W13 and between the wiring W31 and the wiring W13 in a plan view. The wiring W20 is arranged between the wiring W30 and the wiring W13 and between the wiring W32 and the wiring W13 in a plan view. As a result, the parasitic capacitance between each transfer transistor and the floating diffusion FD can be reduced.

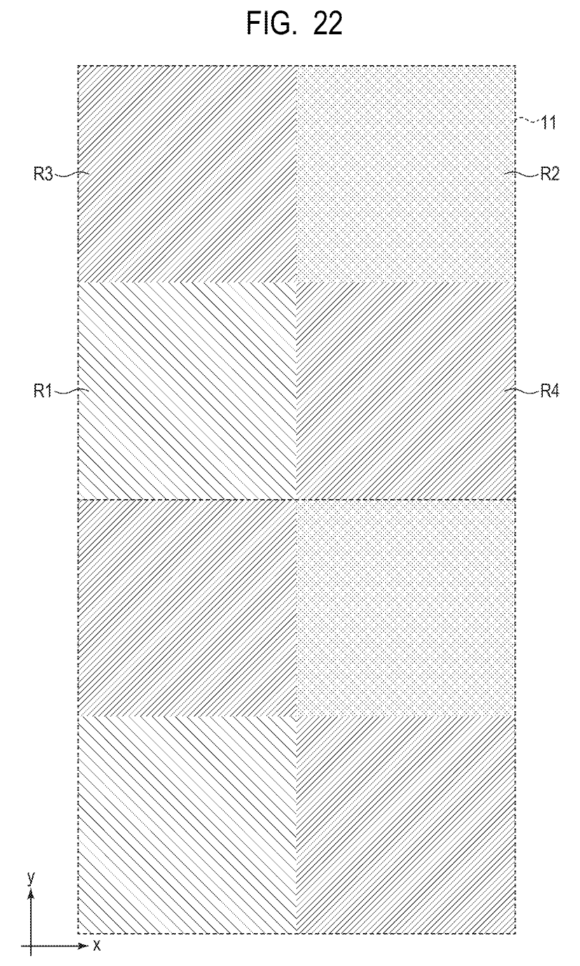

FIG. 22 is a plan view illustrating an arrangement example of color filters according to the present embodiment. FIG. 22 schematically illustrates an example of an arrangement method of color filters of three colors arranged corresponding to the two pixels 11 illustrated in FIG. 21. In FIG. 22, a red color filter is arranged in a region R1. A blue color filter is arranged in a region R2. Green color filters are arranged in a region R3 and a region R4, respectively. The photoelectric conversion units PDA and PDC in the region R1 have sensitivity to red light, the photoelectric conversion units PDF and PDH in the region R2 have sensitivity to blue light, and the photoelectric conversion units PDB, PDD, PDE, and PDG in the regions R3 and R4 have sensitivity to green light. Here, as can be understood by comparing FIG. 21 and FIG. 22, the wiring density in the region R1 that receives light of a relatively long wavelength is higher than any of the wiring densities in the regions R2, R3, and R4 that receive light of a relatively short wavelength. Thus, the sensitivity of the red pixel can be further improved for the same reason as described in the eighth embodiment.

Also in the present embodiment, as in the first to eighth embodiments, the photoelectric conversion device 1 capable of improving the signal quality is provided.

### Tenth Embodiment

In the present embodiment, a modification regarding an arrangement of the wiring connected to the drain of the capacitance addition transistor M5 and the wiring connected to the gate electrode GM5 of the capacitance addition transistor M5 will be described. In the present embodiment, description of elements common to the first to ninth embodiments may be omitted or simplified.

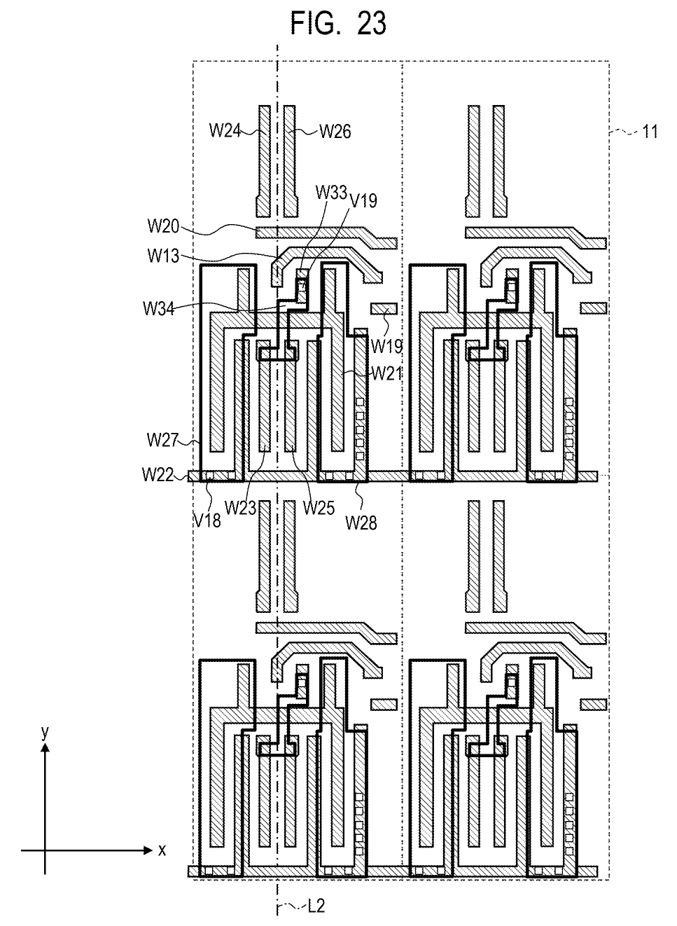

FIG. 23 is a plan view illustrating a configuration example of the pixel 11 according to the present embodiment. FIG. 23 schematically illustrates an arrangement of a wiring W33 connected to the gate electrode GM5 of the capacitance addition transistor M5, a wiring W34 (seventh wiring) arranged in an upper layer than the wiring W33, and a via V19 connecting the wiring W33 and the wiring W34 in a plan view. The configuration of other elements in FIG. 23 is similar to that in FIG. 17, and thus description thereof is omitted.

The wiring W33 and the wiring W34 are supplied with a constant potential in a signal reading period. In a plan view, the wiring W34 and the wiring W21, which is connected to the drain of the capacitance addition transistor M5, are arranged so as to at least partially overlap each other.

The wiring W34 functions as a part of the capacitive element C1 because an interwire capacitance due to electrostatic coupling is generated between the wiring W21 and the wiring W34. Since the capacitance of the capacitive element C1 is larger than that in a case where the wiring W34 is not arranged, the conversion efficiency from the charge to the voltage in the floating diffusion FD in a case where the capacitance addition transistor M5 is in the ON state is lowered. Accordingly, for example, it is possible to suppress whiteout of an image when capturing a bright object.

Since the wiring W21 is connected to the drain of the capacitance addition transistor M5 and the wiring W33 is connected to the gate electrode GM5 of the capacitance addition transistor M5, the wiring W21 and the wiring W33 are arranged at positions close to each other. Therefore, the wiring length of the wiring W34 can be shortened in a case where the wiring W33 is connected to the gate electrode GM5 of the capacitance addition transistor M5 as in the present embodiment as compared with a case where the wiring W33 is connected to a gate electrode of another transistor. Therefore, the degree of freedom of layout of other wirings can be improved.

Also in the present embodiment, as in the first to ninth embodiments, the photoelectric conversion device 1 capable of improving signal quality is provided.

### Eleventh Embodiment

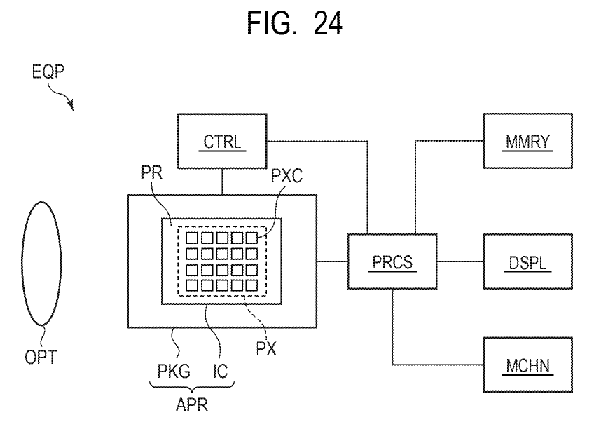

Equipment according to an eleventh embodiment will be described with reference to FIG. 24. FIG. 24 is a block diagram illustrating a schematic configuration of equipment according to the present embodiment.

FIG. 24 is a schematic diagram illustrating equipment EQP including a photoelectric conversion device APR. The photoelectric conversion device APR has the function of the photoelectric conversion device 1 according to the first to tenth embodiments. All or part of the photoelectric conversion device APR is a semiconductor device IC. The photoelectric conversion device APR of this example can be used as, for example, an image sensor, an auto focus (AF) sensor, a photometric sensor, a ranging sensor, or the like. The semiconductor device IC has a pixel area PX in which pixel circuits PXC each including photoelectric conversion unit are arranged in a matrix. The semiconductor device IC may have a peripheral area PR around the pixel area PX. Circuits other than the pixel circuits can be arranged in the peripheral area PR.

The photoelectric conversion device APR may have a structure (stacked chips structure) in which a first semiconductor chip provided with a plurality of photoelectric conversion units and a second semiconductor chip provided with a peripheral circuit are stacked. Each of the peripheral circuits in the second semiconductor chip may be a column circuit corresponding to a pixel column of the first semiconductor chip. Each of the peripheral circuits in the second semiconductor chip may be a matrix circuit corresponding to a pixel or a pixel block in the first semiconductor chip. For the connection between the first semiconductor chip and the second semiconductor chip, a through electrode (TSV), an inter-chip wiring by direct bonding of a conductor such as copper, a connection by a micro bump between chips, a connection by wire bonding, or the like can be employed.

The photoelectric conversion device APR may include a package PKG for mounting the semiconductor device IC in addition to the semiconductor device IC. The package PKG may include a base body to which the semiconductor device IC is fixed, a lid such as glass facing the semiconductor device IC, and a connection member such as a bonding wire or a bump for connecting a terminal provided on the base body and a terminal provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR, and is, for example, a lens, a shutter, or a mirror. The control device CTRL controls the photoelectric conversion device APR, and is, for example, a semiconductor device such as an ASIC.

The processing device PRCS processes a signal output from the photoelectric conversion device APR, and constitutes an analog front end (AFE) or a digital front end (DFE). The processing device PRCS is a semiconductor device such as a central processing unit (CPU) or an application specific integrated circuit (ASIC). The display device DSPL is an EL display device, a liquid crystal display device, or the like that displays information (image) obtained by the photoelectric conversion device APR. The storage device MMRY is a magnetic device, a semiconductor device, or the like that stores information (image) obtained by the photoelectric conversion device APR. The storage device MMRY is a volatile memory such as an SRAM or a DRAM, or a nonvolatile memory such as a flash memory or a hard disk drive.

The mechanical device MCHN includes a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, the equipment EQP may further include a storage device MMRY and a processing device PRCS separately from the storage circuit unit and the arithmetic circuit unit included in the photoelectric conversion device APR. The mechanical device MCHN may be controlled based on a signal output from the photoelectric conversion device APR.

The equipment EQP illustrated in FIG. 24 may be an electronic device such as an information terminal (for example, a smartphone and a wearable terminal) having a photographing function, a camera (For example, an interchangeable lens camera, a compact camera, a video camera, and a surveillance camera), or the like. The mechanical device MCHN in the camera may drive parts of the optical device OPT for zooming, focusing, and shutter operation. Also, the equipment EQP may be a transport device (movable body) such as a vehicle, a ship, a drone, or an airplane. The equipment EQP may be a medical device such as an endoscope or a CT scanner. The equipment EQP may be a measurement device such as a ranging sensor, an analysis device such as an electron microscope, an office device such as a copier, or an industrial device such as a robot.

The mechanical device MCHN in the transport device may be used as a movable device. The equipment EQP as a transport device is suitable for transporting the photoelectric conversion device APR, or for assisting and/or automating driving (manipulation) by an imaging function. The processing device PRCS for assisting and/or automating driving (manipulation) may perform processing for operating the mechanical device MCHN as a movable device based on information obtained by the photoelectric conversion device APR.

According to the first to tenth embodiments, signal acquisition can be performed satisfactorily. Therefore, the photoelectric conversion device APR according to the first to tenth embodiments may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP. Here, increasing the value corresponds to at least one of adding a function, improving performance, improving characteristics, improving reliability, improving manufacturing yield, reducing environmental load, reducing cost, reducing size, and reducing weight.

For example, by mounting the photoelectric conversion device APR in a transport device, it is possible to obtain excellent performance when photographing outside the transport device or measuring an external environment. Therefore, in manufacturing and selling the transport device, it is advantageous to determine the mounting of the photoelectric conversion device APR according to the present embodiment on the transport device in order to improve the performance of the transport device itself. In particular, the photoelectric conversion device APR is suitable for a transport device that performs driving support and/or automatic driving of the transport device using information obtained by the photoelectric conversion device APR.

### Twelfth Embodiment

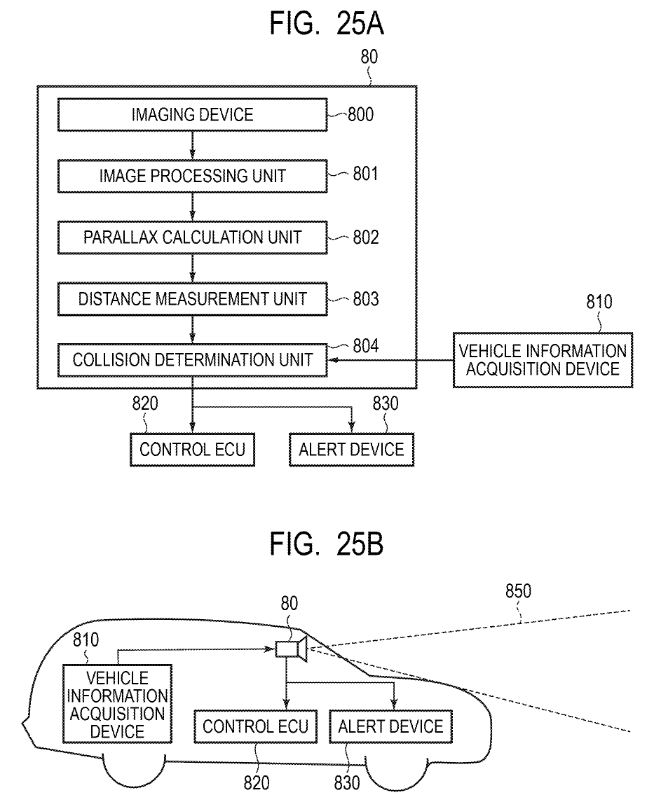

FIGS. 25A and 25B are block diagrams of equipment relating to the vehicle-mounted camera according to the present embodiment. FIGS. 25A and 25B illustrate an example in which the photoelectric conversion device is applied to a movable body such as a vehicle. The equipment 80 includes an imaging device 800 (an example of the photoelectric conversion device) and a signal processing device (processing device) that processes a signal from the imaging device 800. The equipment 80 includes an image processing unit 801 that performs image processing on a plurality of pieces of image data acquired by the imaging device 800, and a parallax calculation unit 802 that calculates parallax (phase difference of parallax images) from the plurality of pieces of image data acquired by the equipment 80.

Here, the equipment 80 may include an optical system (not illustrated) that guides light to the imaging device 800. The optical system may include, for example, a lens, a shutter, and a mirror. A plurality of photoelectric conversion units substantially conjugate to the pupil of the optical system may be arranged in a pixel included in the imaging device 800. For example, a plurality of photoelectric conversion units are arranged corresponding to one microlens. The plurality of photoelectric conversion units may receive light fluxes transmitted through different positions of the pupil of the optical system. Thus, the imaging device 800 outputs a plurality of pieces of image data respectively corresponding to the light fluxes transmitted through different positions of the pupil of the optical system. Then, the parallax calculation unit 802 may calculate the parallax using the plurality of pieces of image data being output.

The equipment 80 includes a distance measurement unit 803 that calculates a distance to an object based on the calculated parallax, and a collision determination unit 804 that determines whether or not there is a possibility of collision based on the calculated distance. Here, the parallax calculation unit 802 and the distance measurement unit 803 are examples of a distance information acquisition unit that acquires distance information to the object. That is, the distance information is information on a parallax, a defocus amount, a distance to the object, and the like. The collision determination unit 804 may determine the possibility of collision using any of these pieces of distance information. Note that the distance information may be acquired using a time of flight (ToF) technique. The distance information acquisition unit may be realized by dedicatedly designed hardware or software modules. Further, it may be realized by a field programmable gate array (FPGA), an application specific integrated circuit (ASIC) or a combination thereof.

The equipment 80 is connected to the vehicle information acquisition device 810, and can obtain vehicle information such as a vehicle speed, a yaw rate, and a steering angle. Further, the equipment 80 is connected to a control ECU 820 which is a control device that outputs a control signal for generating a braking force to the vehicle based on the determination result of the collision determination unit 804. The equipment 80 is also connected to an alert device 830 that issues an alert to the driver based on the determination result of the collision determination unit 804. For example, when the collision possibility is high as the determination result of the collision determination unit 804, the control ECU 820 performs vehicle control to avoid collision or reduce damage by braking, returning an accelerator, suppressing engine output, or the like. The alert device 830 alerts the user by sounding an alarm such as a sound, displaying alert information on a screen of a car navigation system or the like, or giving vibration to a seat belt or a steering wheel. The equipment 80 functions as a control unit that controls the operation of controlling the vehicle as described above.

In the present embodiment, an image of the periphery of the vehicle, for example, the front or the rear is captured by the equipment 80. FIG. 25B illustrates equipment in a case where an image is captured in front of the vehicle (image capturing range 850). The vehicle information acquisition device 810 as the imaging control unit sends an instruction to the equipment 80 or the imaging device 800 to perform the imaging operation. With such a configuration, the accuracy of distance measurement can be further improved.

Although the example of control for avoiding a collision to another vehicle has been described above, the embodiment is applicable to automatic driving control for following another vehicle, automatic driving control for not going out of a traffic lane, or the like. Furthermore, the equipment is not limited to a vehicle such as an automobile and can be applied to a movable body (movable apparatus) such as a ship, an airplane, a satellite, an industrial robot and a consumer use robot, or the like, for example. In addition, the equipment can be widely applied to equipment which utilizes object recognition or biometric authentication, such as an intelligent transportation system (ITS), a surveillance system, or the like without being limited to movable bodies.

### Other Embodiments

The present disclosure is not limited to the above embodiments, and various modifications are possible. For example, an example in which some of the configurations of any one of the embodiments are added to other embodiments or an example in which some of the configurations of any one of the embodiments are replaced with some of the configurations of other embodiments are also embodiments of the present disclosure.

The embodiments described above can be appropriately modified without departing from the technical idea. Note that the disclosure of the present specification includes not only the matters described in the present specification but also all matters that can be grasped from the present specification and the drawings attached to the present specification. Also, the disclosure of the present specification includes a complementary set of the concepts described in the present specification. In other words, for example, when there is a description of "A is greater than B" in the present specification, it can be said that the description of "A is not greater than B" is disclosed in the present specification even when the description of "A is not greater than B" is omitted. This is because it is assumed that the case where "A is not greater than B" is considered when "A is greater than B" is described.

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

It should be noted that the above-described embodiments are merely specific examples for carrying out the present disclosure, and the technical scope of the present disclosure should not be interpreted in a limited manner by these embodiments. That is, the present disclosure can be implemented in various forms without departing from the technical idea or the main features thereof.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-068401, filed Apr. 17, 2025, and Japanese Patent Application No. 2026-008099, filed Jan. 21, 2026, which are hereby incorporated by reference herein in their entirety.

What is claimed is:

1. A photoelectric conversion device comprising:
a semiconductor substrate;
a first photoelectric conversion unit formed in the semiconductor substrate;
a floating diffusion formed in the semiconductor substrate;
a first transfer transistor formed in the semiconductor substrate and configured to transfer charges from the first photoelectric conversion unit to the floating diffusion;
a first wiring connected to a gate electrode of the first transfer transistor;
a second wiring connected to the floating diffusion;
a third wiring to which a predetermined potential is applied;
a fourth wiring arranged at least partially side by side with the third wiring and generating a capacitance with the third wiring; and
a capacitance addition transistor formed in the semiconductor substrate and having a first main electrode connected to the floating diffusion and a second main electrode connected to the fourth wiring,
wherein in a plan view with respect to the semiconductor substrate, the fourth wiring is arranged between the first wiring and the second wiring.

2. The photoelectric conversion device according to claim 1, wherein the first wiring, the second wiring, and the fourth wiring are arranged in a same layer.

3. The photoelectric conversion device according to claim 1, wherein the third wiring and the fourth wiring are arranged in a same layer.

4. The photoelectric conversion device according to claim 1, wherein at least a part of the third wiring is arranged in a layer different from that of the fourth wiring.

5. The photoelectric conversion device according to claim 4, wherein in the plan view, the third wiring overlaps the fourth wiring at least partially.

6. The photoelectric conversion device according to claim 1, wherein the fourth wiring is arranged in a layer closer to the semiconductor substrate than the first wiring and the second wiring.

7. The photoelectric conversion device according to claim 1 further comprising:
a second photoelectric conversion unit formed in the semiconductor substrate;
a second transfer transistor formed in the semiconductor substrate and configured to transfer charges from the second photoelectric conversion unit to the floating diffusion;
a fifth wiring connected to a gate electrode of the second transfer transistor; and
a sixth wiring arranged between the second wiring and the fifth wiring in the plan view.

8. The photoelectric conversion device according to claim 7, wherein in the plan view, the fourth wiring is not arranged between the second wiring and the fifth wiring.

9. The photoelectric conversion device according to claim 7 further comprising an amplification transistor configured to output a signal according to a potential of the floating diffusion,
wherein the sixth wiring is connected to a main electrode of the amplification transistor.

10. The photoelectric conversion device according to claim 7 further comprising:
an amplification transistor configured to output a signal according to a potential of the floating diffusion;
a first output signal line and a second output signal line;
a first selection transistor configured to output a signal from the amplification transistor to the first output signal line by being turned on; and
a second selection transistor configured to output a signal from the amplification transistor to the second output signal line by being turned on,
wherein the sixth wiring is connected to main electrodes of the amplification transistor, the first selection transistor, and the second selection transistor.

11. The photoelectric conversion device according to claim 7 further comprising:
an amplification transistor configured to output a signal according to a potential of the floating diffusion;
a first output signal line and a second output signal line;
a first selection transistor configured to output a signal from the amplification transistor to the first output signal line by being turned on;
a second selection transistor configured to output a signal from the amplification transistor to the second output signal line by being turned on; and
a first semiconductor region and a second semiconductor region each arranged in the semiconductor substrate,
wherein the first semiconductor region constitutes a main electrode of the first selection transistor and a main electrode of the amplification transistor,
wherein the second semiconductor region constitutes a main electrode of the second selection transistor and a main electrode of the amplification transistor, and
wherein the sixth wiring is connected to at least one of the first semiconductor region and the second semiconductor region.

12. The photoelectric conversion device according to claim 1 further comprising:
a third photoelectric conversion unit formed in the semiconductor substrate;
a third transfer transistor formed in the semiconductor substrate and configured to transfer charges from the third photoelectric conversion unit to the floating diffusion; and
a microlens arranged to guide incident light to the first photoelectric conversion unit and the third photoelectric conversion unit.

13. The photoelectric conversion device according to claim 1,
wherein the semiconductor substrate has a first face and a second face opposite to the first face,
wherein the first wiring, the second wiring, the third wiring, and the fourth wiring are arranged on a side of the first face, and
wherein the first photoelectric conversion unit has sensitivity to light incident on the second face.

14. The photoelectric conversion device according to claim 13 further comprising a fourth photoelectric conversion unit formed in the semiconductor substrate,
wherein the first photoelectric conversion unit has sensitivity to light having a first wavelength,
wherein the fourth photoelectric conversion unit has sensitivity to light having a second wavelength shorter than the first wavelength, and
wherein a wiring density in a region in which the first photoelectric conversion unit is arranged is higher than a wiring density in a region in which the fourth photoelectric conversion unit is arranged.

15. The photoelectric conversion device according to claim 14,
wherein the first photoelectric conversion unit has sensitivity to red light, and
wherein the fourth photoelectric conversion unit has sensitivity to blue light.

16. The photoelectric conversion device according to claim 14 further comprising a fourth transfer transistor formed in the semiconductor substrate and configured to transfer charges from the fourth photoelectric conversion unit to the floating diffusion.

17. The photoelectric conversion device according to claim 1 further comprising a reset transistor configured to reset a potential of the floating diffusion by being turned on,
wherein the fourth wiring is connected to a main electrode of the reset transistor.

18. The photoelectric conversion device according to claim 1 further comprising:
a reset transistor configured to reset a potential of the floating diffusion by being turned on; and
a third semiconductor region arranged in the semiconductor substrate,
wherein the third semiconductor region constitutes the first main electrode of the capacitance addition transistor and a main electrode of the reset transistor.

19. The photoelectric conversion device according to claim 1 further comprising a seventh wiring connected to a gate electrode of the capacitance addition transistor,
wherein the seventh wiring overlaps at least a part of the fourth wiring in the plan view.

20. Equipment comprising:
the photoelectric conversion device according to claim 1; and
at least any one of:
an optical device adapted for the photoelectric conversion device,
a control device configured to control the photoelectric conversion device,
a processing device configured to process a signal output from the photoelectric conversion device,
a display device configured to display information obtained by the photoelectric conversion device,
a storage device configured to store information obtained by the photoelectric conversion device, and
a mechanical device configured to operate based on information obtained by the photoelectric conversion device.

21. The equipment according to claim 20, wherein the processing device acquires information on a distance from the photoelectric conversion device to an object.
